(19) United States
(12) Patent Application Publication
(10) Pub. No.: US 2019/0238157 A1
(43) Pub. Date: Aug. 1, 2019

(54) LDPC ENCODER AND LDPC ENCODING METHOD

(71) Applicant: ELECTRONICS AND TELECOMMUNICATIONS RESEARCH INSTITUTE, Daejeon (KR)

(72) Inventors: Hyuk KIM, Daejeon (KR); In-San JEON, Daejeon (KR)

(73) Assignee: ELECTRONICS AND TELECOMMUNICATIONS RESEARCH INSTITUTE, Daejeon (KR)

(21) Appl. No.: 16/166,789

(22) Filed: Oct. 22, 2018

(30) Foreign Application Priority Data
Jan. 26, 2018 (KR) 10-2018-0010212

(51) Int. Cl. H03M 13/11; H03M 13/00

(52) U.S. Cl. CPC H03M 13/116; H03M 13/618; H03M 13/611; H03M 13/616

(57) ABSTRACT

An LDPC encoding method of a computing device is provided. The computing device performs LDCP encoding on information with a parity check matrix with R rows and (C+R) columns defining an LDPC code. When the parity check matrix is divided into a first matrix with R rows and R columns and a second matrix with R rows and R columns, each element of the first matrix indicates a number of times an identity matrix with Z rows and Z columns are circularly shifted. All elements in the first row of the first matrix are 0. In the r-th row of the first matrix, elements obtained by performing a modulo Z operation (mod Z) on values which are sequentially incremented by (r−1) starting from 0 are arranged. R, C, and Z are natural numbers, and r is an integer from 2 to R.

### CROSS-REFERENCE TO RELATED APPLICATION

This application claims priority to and the benefit of Korean Patent Application No. 10-2018-0010212 filed in the Korean Intellectual Property Office on Jan. 26, 2018, the entire contents of which are incorporated herein by reference.

### BACKGROUND

### (a) Field

The present invention generally relates to a low-density parity-check (LDPC) encoder and an LDPC encoding method.

### (b) Description of the Related Art

LDPC codes are error-correcting codes which were originally proposed by Gallager in 1962, but were ignored until they were rediscovered by MacKay and Neal in 1996 due to technical limitations. However, the LDPC codes have error-correcting performance which approaches the Shannon limit as closely as possible among forward error-correcting techniques, and are adopted in various communication standards and storage media systems. In addition, since error-correcting codes are indispensable in ultrahigh-speed optical communication systems such as optical communication systems supporting transmission rates of 100 Gbps or more, the LDPC codes are also used in the ultrahigh-speed optical communication systems. Further, many studies are being conducted for real-time applications of the LDPC codes.

The LDPC code can be represented as Tanner graph. For example, it is assumed that there is an arbitrary code c with six elements, as in Equation 1.

C=[c₁c₂c₃c₄c₅c₆] Equation 1

It is assumed that the above code c satisfies three parity check equations as Equation 2.

$$\{ \begin{matrix}{c}_{1} ⊕ {c}_{2} ⊕ {c}_{4} = 0 \\ {c}_{2} ⊕ {c}_{3} ⊕ {c}_{5} = 0 \\ {c}_{1} ⊕ {c}_{2} ⊕ {c}_{3} ⊕ {c}_{6} = 0\end{matrix} \qquad Equation 2$$

This relationship is expressed by a parity check matrix (H) as in Equation 3.

$$[ \begin{matrix}1 & 1 & 0 & 1 & 0 & 0 \\ 0 & 1 & 1 & 0 & 1 & 0 \\ 1 & 1 & 1 & 0 & 0 & 1\end{matrix} ] [ \begin{matrix}{c}_{1} \\ {c}_{2} \\ {c}_{3} \\ {c}_{4} \\ {c}_{4} \\ {c}_{6}\end{matrix} ] = [ \begin{matrix}0 \\ 0 \\ 0\end{matrix} ] \qquad Equation 3$$

Therefore, the code c becomes a valid codeword if it satisfies Equation 4 for the parity check matrix H.

Hc^{T}=0 Equation 4

Generally, a generator matrix is used to encode a block code. However, since the LDPC code is defined by the parity check matrix rather than the generator matrix, the LDPC code should be encoded by converting the parity check matrix into the generator matrix. This requires a process for obtaining the inverse matrix. The process is complicated and it is also difficult to implement the process in hardware.

### SUMMARY

An embodiment of the present invention provides an LDPC encoder and an LDPC encoding method for capable of performing LDPC encoding without complications.

According to an embodiment of the present invention, an LDPC encoding method of a computing device is provided. The LDPC encoding method includes providing a parity check matrix with R rows and (C+R) columns defining an LDPC code, and performing LDCP encoding on information with the parity check matrix. When the parity check matrix is divided into a first matrix with R rows and R columns and a second matrix with R rows and R columns, each element of the first matrix indicates a number of times an identity matrix with Z rows and Z columns are circularly shifted. All elements in the first row of the first matrix are 0. In the r-th row of the first matrix, elements obtained by performing a modulo Z operation (mod Z) on values which are sequentially incremented by (r−1) starting from 0 are arranged. Here, R, C, and Z are natural numbers, and r is an integer from 2 to R.

In the second matrix, a (r′,r′) element may be 0 indicating an identity matrix with Z rows and Z columns, and remaining elements may be −1 indicating a zero matrix with Z rows and Z columns. Here, r′ is an integer from 1 to R.

When a certain element obtained by performing the modulo Z operation is equal to any one of previously arranged elements in the r-th row, the certain element may be incremented by 1.

C may be equal to Z.

C may be smaller than Z.

R may be 4.

According to another embodiment of the present invention, an LDPC encoding method of a computing device is provided. The LDPC encoding method includes sequentially inputting C blocks in units of Z bits into which information is divided. The LDPC encoding method further includes performing a bitwise XOR operation on each of the sequentially inputted blocks and Z bits stored in a first register, storing a result of the bitwise XOR operation in the first register, and outputting a final value stored in the first register as the first parity information. The LDPC encoding method further includes circularly shifting each of the sequentially inputted blocks by a circular-shift value corresponding to a value obtained by performing a modulo Z operation on a value which increments by (r−1) starting from 0, performing a bitwise XOR operation on the circularly-shifted value and Z bits stored in a r-th register, storing a result of the bitwise XOR operation in the r-th register, and outputting a final value stored in the r-th register as the r-th parity information. The LDPC encoding method further includes generating parity by sequentially outputting the first parity information and the r-th parity information. Here, Z, C, and R are natural numbers, and r is an integer from 2 to (R−1).

Circularly shifting each of the sequentially inputted blocks may include generating the value obtained by performing the modulo Z operation as the circular-shift value when the value obtained by performing the modulo Z operation is not equal to previously generated circular-shift values, and generating a sum of one and the value obtained by performing the modulo Z operation as the circular-shift value when the value obtained by performing the modulo Z operation is equal to any one of the previously generated circular-shift values.

When r is 2, circularly shifting each of the sequentially inputted blocks may includes incrementing a counted value by 1 starting from 0 whenever the C blocks are sequentially inputted, and outputting the counted value or a value obtained by performing the modulo Z operation on the counted value as the circular-shifted value.

When r is an integer from 3 to (R−1), circularly shifting each of the sequentially inputted blocks may includes multiplying the counted value or the value obtained by performing the modulo Z operation on the counted value by (r−1), and generating the circular-shifted value using a value obtained by performing the modulo Z operation on the multiplied value.

When r is an integer from 3 to (R−1), circularly shifting each of the sequentially inputted blocks may further includes outputting the value obtained by performing the modulo Z operation on the multiplied value as the circular-shift value when the value obtained by performing the modulo Z operation on the multiplied value is not equal to previously generated circular-shift values, and outputting a sum of one and the value obtained by performing the modulo Z operation on the multiplied value as the circular-shift value when the value obtained by performing the modulo Z operation on the multiplied value is equal to any one of the previously generated circular-shift values.

The LDPC encoding method may further include outputting a codeword by combining the information with the parity.

C may be equal to Z.

C may be smaller than Z.

R may be 4.

According to yet another embodiment of the present invention, an LDPC encoder to which C blocks in units of Z bits into which information is divided are sequentially inputted is provided. The LDPC encoder includes R parity information generators. The first parity information generator among the R parity information generators includes a first XOR operator and a first register, and the first XOR operator performs a bitwise XOR operation on each of the sequentially inputted blocks and Z bits stored in the first register and stores a result of the bitwise XOR operation in the first register. The r-th parity information generator among the R parity information generators includes a r-th XOR operator and a r-th register, and the r-th XOR operator performs a bitwise XOR operation on a circularly-shifted value and Z bits stored in the r-th register and stores a result of the bitwise XOR operation in the r-th register. The circularly-shifted value is obtained by circularly shifting each of the sequentially inputted blocks by a circular-shift value corresponding to a value obtained by performing a modulo Z operation on a value which increments by (r−1) starting from 0. Here, Z, C, and R are natural numbers, and r is an integer from 2 to (R−1).

When r is 2, the r-th parity information generator may further include a counter. The counter may increment a counted value by 1 starting from 0 whenever the C blocks are sequentially inputted, and output the counted value or a value obtained by performing the modulo Z operation on the counted value as the circular-shifted value.

When r is an integer from 3 to (R−1), the r-th parity information generator may further include a (r−1)-multiplied modulo Z operator. The (r−1)-multiplied modulo Z operator may multiply the value obtained by performing the modulo Z operation on an output of the counter by (r−1), and generate the circular-shifted value using a value obtained by performing the modulo Z operation on the multiplied value.

The (r−1)-multiplied modulo Z operator may output the value obtained by performing the modulo Z operation on the multiplied value as the circular-shift value when the value obtained by performing the modulo Z operation on the multiplied value is not equal to previously generated circular-shift values, and may output a sum of one and the value obtained by performing the modulo Z operation on the multiplied value as the circular-shift value when the value obtained by performing the modulo Z operation on the multiplied value is equal to any one of the previously generated circular-shift values.

A codeword may outputted by combining the information with outputs of the R parity information generators.

According to an embodiment of the present invention, an LDPC encoder and an LDPC encoding method can provide a good BER performance without complications.

### BRIEF DESCRIPTION OF THE DRAWINGS

FIG. 1 is a drawing showing a parity check matrix according to an embodiment of the present invention.

FIG. 2 is a drawing explaining circular-shift of a Z×Z identity matrix.

FIG. 3 is a drawing showing a method of a parity check matrix defining an LDPC code according to an embodiment of the present invention.

FIG. 4 is a schematic block diagram of the i-th parity information generator in an LDPC encoder according to an embodiment of the present invention.

FIG. 5 is a schematic block diagram of an LDPC encoder according to an embodiment of the present invention.

FIG. 6 is a schematic block diagram of an LDPC encoder according to another embodiment of the present invention.

FIG. 7 is a drawing showing a performance of an LDPC code according to an embodiment of the present invention.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

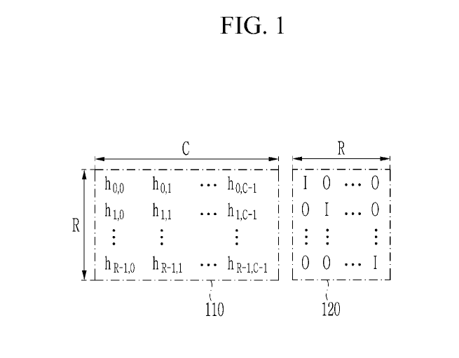

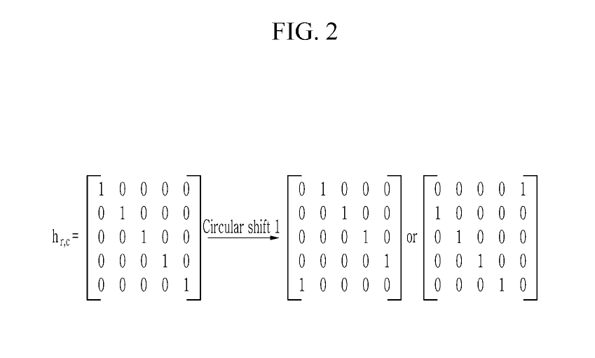

FIG. 1 is a drawing showing a parity check matrix according to an embodiment of the present invention, and FIG. 2 is a drawing explaining circular-shift of a Z×Z identity matrix.

According to an embodiment of the present invention, an LDPC code is defined by a parity check matrix shown in FIG. 1.

Referring to FIG. 1, in a basic parity check matrix H, the number of rows is R and the number of columns is (C+R). C is the number of columns which transmitting information occupies among the columns of the parity check matrix H. That is, the number (C+R) of total columns is equal to a sum of the number (C) of columns occupied by the transmitting information and the number (R) of rows. The columns added to the columns occupied by the transmitting information are used to generate parity. Accordingly, the parity check matrix H may be divided into an H1 matrix 110 which is a part occupied by the transmitting information and an H2 matrix 120 which is a part for parity generation. The H1 matrix 110 is an R×C matrix, and the H2 matrix 120 is an R×R matrix.

An h_{r,c} element of the H1 matrix 110 is obtained by circularly shifting the Z×Z identity matrix at a position (r, c) by a predetermined number of times. For example, assuming that Z is five and the number of circular-shift is one, the h_{r,c} element may have a form shown in FIG. 2. In the H2 matrix 120, 0 denotes a zero matrix, and I denotes an identity matrix.

A code rate and an overhead of the LDPC code are determined as in Equations 5 and 6, respectively.

Code Rate=C/(C+R) Equation 5

Overhead=R/C[%] Equation 6

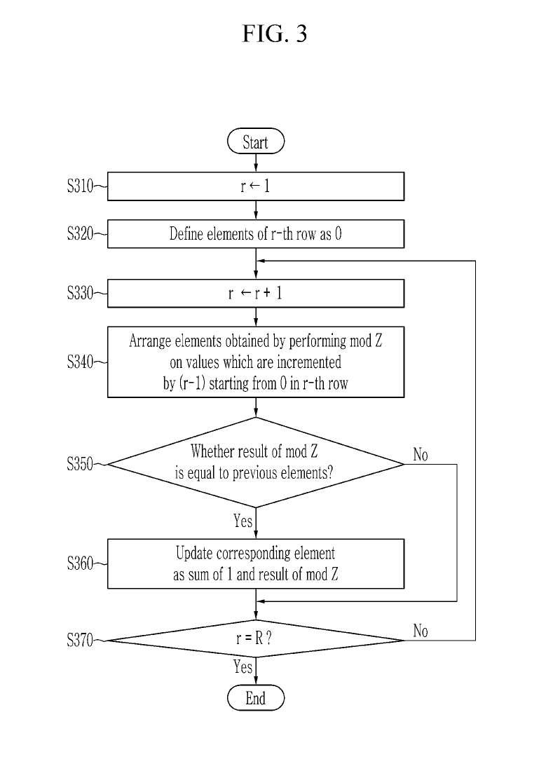

FIG. 3 is a drawing showing a method of a parity check matrix defining an LDPC code according to an embodiment of the present invention.

Referring to FIG. 3, elements of the first row in an H1 matrix of a parity check matrix are defined as 0 (S310 and S320). Next, elements of the second to R-th rows in the H1 matrix are defined (S330 to S370). In the r-th row of the H1 matrix, elements obtained by performing a modulo Z operation (mod Z) on values which are sequentially incremented by (r−1) starting from 0 are arranged (S340). If a certain element obtained by performing the modulo Z operation is equal to any one of the previously arranged elements (S350), the certain element is incremented by 1 (S360). Her, r is an integer from 2 to R.

On the other hand, in an H2 matrix, (r,r) elements are defined as 0 indicating a Z×Z identity matrix and the remaining elements are defined as −1 indicating a Z×Z zero matrix. Her, r is an integer from 1 to R.

Next, various examples of the parity check matrix of the LDPC code described with reference to FIG. 3 are described.

An example of the LDPC code according to an embodiment of the present invention may use variables of R=4, C=53, and Z=53 in the parity check matrix described with reference to FIG. 1 and FIG. 3. This LDPC code is referred to as “LDPC code 1”.

The parity check matrix of the LDPC code 1 has a format of 4 rows and 57 columns where a code rate is 53/57(=0.9298) and an overhead is 4/53(=7.547%). The overhead represents an amount of parity to be added relative to an amount of information. Since the code rates are 1/2, 2/3, 3/4, and 5/6 in the LDPC code used in a wireless LAN, the overheads are 100%, 50%, 33.3%, and 20%, respectively. Therefore, the LDPC code according to an embodiment of the present invention is a code having a very low overhead.

In the LDPC code 1, an information length K is 53×53=2809, and a code length N is 53×57=3021. Therefore, the LDPC code 1 is a (3021,2809) LDPC code when represented as an (N,K) block code. As described with reference to FIG. 3, in the LPDC code 1, four rows may be defined as following sequences where the number of each row is 57.

The first row: 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 −1 −1 −1

The second row: 0 1 2 3 4 5 6 7 8 9 10 11 12 13 14 15 16 17 18 19 20 21 22 23 24 25 26 27 28 29 30 31 32 33 34 35 36 37 38 39 40 41 42 43 44 45 46 47 48 49 50 51 52 −1 0 −1 −1

The third row: 0 2 4 6 8 10 12 14 16 18 20 22 24 26 28 30 32 34 36 38 40 42 44 46 48 50 52 1 3 5 7 9 11 13 15 17 19 21 23 25 27 29 31 33 35 37 39 41 43 45 47 49 51 −1 −1 0 −1

The fourth row: 0 3 6 9 12 15 18 21 24 27 30 33 36 39 42 45 48 51 1 47 10 13 16 19 22 25 28 31 34 37 40 43 46 49 52 2 5 8 11 14 17 20 23 26 29 32 35 38 41 44 47 50 −1 −1 −1 0

In the above-described sequences, each number indicates circularly shifting the 53×53 identity matrix by that number. Accordingly, the number ‘0’ indicates the identity matrix because it means not circularly shifting the identity matrix, and the number ‘−1’ indicates a zero matrix.

In another embodiment, a shortened code of a basic code may be used as the LPDC code. The shortened code is a code where R is maintained and C is decreased in the basic parity check matrix shown in FIG. 1. In the shortened code, a code rate is decreased but an overhead is increased. As another example of the LDPC code, a shortened code in which the sequences of a basic code, i.e., the LDPC code 1 are modified may be used.

As an example of the shortened code, a (2703,2491) LDPC code (hereinafter referred to as “LDPC code 2”) with R=4, C=47, and Z=53 may be used. As another example of the shortened code, a (2448,2256) LDPC code (hereinafter referred to as “LDPC code 3”) with R=4, C=47, and Z=48 may be used. As yet another example of the shortened code, a (239,2209) LDPC code (hereinafter referred to as “LDPC code 4”) with R=4, C=47, and Z=47 may be used. In these LDPC codes, a code rate is 47/51=0.9216 and an overhead is 8.51%. Sequences of a basic parity check matrix in each LDPC code is given as follows.

In the LPDC code 2, four rows may be defined as following sequences where the number of each row is 51.

The first row: 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 −1 −1 −1

The second row: 0 1 2 3 4 5 6 7 8 9 10 11 12 13 14 15 16 17 18 19 20 21 22 23 24 25 26 27 28 29 30 31 32 33 34 35 36 37 38 39 40 41 42 43 44 45 46 −1 0 −1 −1

The third row: 0 2 4 6 8 10 12 14 16 18 20 22 24 26 28 30 32 34 36 38 40 42 44 46 48 50 52 1 3 5 7 9 11 13 15 17 19 21 23 25 27 29 31 33 35 37 39 −1 −1 0 −1

The fourth row: 0 3 6 9 12 15 18 21 24 27 30 33 36 39 42 45 48 51 1 47 10 13 16 19 22 25 28 31 34 37 40 43 46 49 52 2 5 8 11 14 17 20 23 26 29 32 −1 −1 −1 0

In the LPDC code 3, four rows may be defined as following sequences where the number of each row is 51. As described with reference to FIG. 3, in the fourth row, an element ‘46’ is incremented by 2 to be 48, and then the modulo 48 operation is performed on 48 to be 0. However, since the element ‘0’ is previously arranged, it is changed to 1 by adding 1 to 0. Elements subsequent to the element ‘1’ can be calculated in the same way. In the fourth row, an element ‘45’ is incremented by 3 to be 48, and then the modulo 48 operation is performed on 48 to be 0. However, since the element ‘0’ is previously arranged, it is changed to 1 by adding 1 to 0. Elements subsequent to the element ‘1’ can be calculated in the same way. In the fourth row, an element ‘46’ is incremented by 3 to be 49, and then the modulo 48 operation is performed on 48 to be 1. However, since the element ‘1’ is previously arranged, it is changed to 2 by adding 1 to 1. Elements subsequent to the element ‘2’ can be calculated in the same way.

The first row: 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 −1 −1 −1

The second row: 0 1 2 3 4 5 6 7 8 9 10 11 12 13 14 15 16 17 18 19 20 21 22 23 24 25 26 27 28 29 30 31 32 33 34 35 36 37 38 39 40 41 42 43 44 45 46 −1 0 −1 −1

The third row: 0 2 4 6 8 10 12 14 16 18 20 22 24 26 28 30 32 34 36 38 40 42 44 46 1 3 5 7 9 11 13 15 17 19 21 23 25 27 29 31 33 35 37 39 41 43 45 −1 −1 0 −1

The fourth row: 0 3 6 9 12 15 18 21 24 27 30 33 36 39 42 45 1 4 7 10 13 16 19 22 25 28 31 34 37 40 43 46 2 5 8 11 14 17 20 23 26 29 32 35 38 41 44 −1 −1 −1 0

In the LPDC code 4, four rows may be defined as following sequences where the number of each row is 51.

The first row: 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 0 −1 −1 −1

The second row: 0 1 2 3 4 5 6 7 8 9 10 11 12 13 14 15 16 17 18 19 20 21 22 23 24 25 26 27 28 29 30 31 32 33 34 35 36 37 38 39 40 41 42 43 44 45 46 −1 0 −1 −1

The third row: 0 2 4 6 8 10 12 14 16 18 20 22 24 26 28 30 32 34 36 38 40 42 44 46 1 3 5 7 9 11 13 15 17 19 21 23 25 27 29 31 33 35 37 39 41 43 45 −1 −1 0 −1 The fourth row: 0 3 6 9 12 15 18 21 24 27 30 33 36 39 42 45 1 4 7 10 13 16 19 22 25 28 31 34 37 40 43 46 2 5 8 11 14 17 20 23 26 29 32 35 38 41 44 −1 −1 −1 0

The LDPC code 2 is the same as a code generated by deleting the 48th to 53rd columns from the basic parity check matrix of the LDPC code 1. The LDPC codes 3 and 4 use the same basic parity check matrix but have different lengths since they use different Z values.

Next, an encoding method using an LDPC code according to an embodiment of the present invention is described. The LDPC encoding according to an embodiment of the present invention may be executed in various computing devices. Particularly, the LDPC encoding may be implemented by a semiconductor design and/or software implemented on the various computing devices.

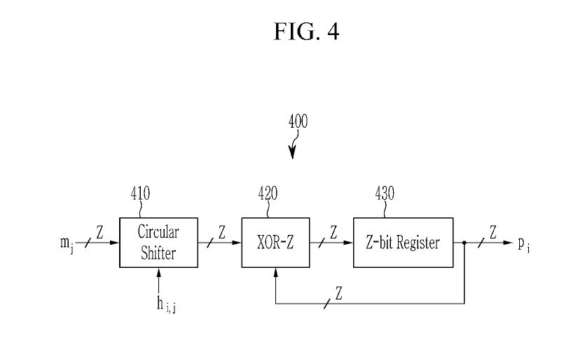

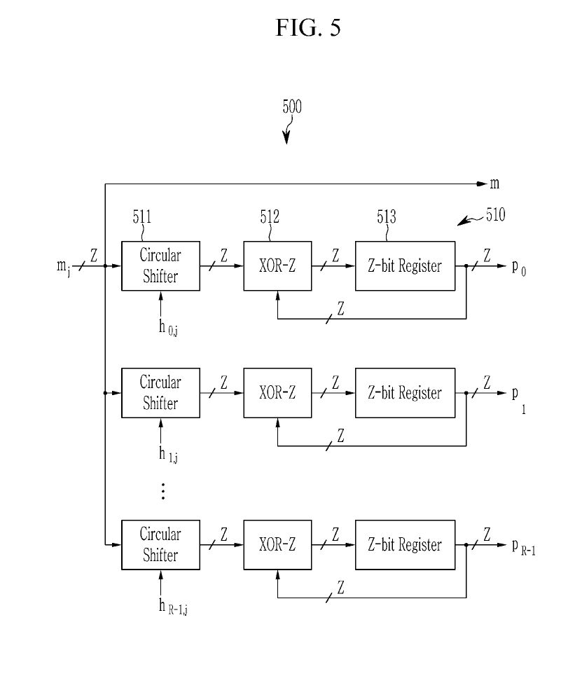

FIG. 4 is a schematic block diagram of the i-th parity information generator in an LDPC encoder according to an embodiment of the present invention, and FIG. 5 is a schematic block diagram of an LDPC encoder according to an embodiment of the present invention.

First, a codeword c obtained by encoding transmitting information m with an LDPC code may be given as in Equation 7.

c=[mp] Equation 7

In Equation 7, p is parity.

As such, the encoding process calculates the parity p corresponding to the transmitting information m to acquire the codeword c.

As described above, since each element of the parity check matrix consists of a Z×Z sub-matrix, the information m can be divided into units of Z bits. That is, the information m can be divided into C blocks (m₀, m₁, . . . m_{C-1}) in units of Z bits. Here, j is an integer from 0 to (C−1). Accordingly, Equation 4 may be defined as in Equation 8.

$$[ \begin{matrix}{h}_{0 , 0} & {h}_{0 , 1} & ⋯ & {h}_{0 , C - 1} & 1 & 0 & ⋯ & 0 \\ {h}_{1 , 0} & {h}_{1 , 1} & ⋯ & {h}_{1 , C - 1} & 0 & 1 & ⋯ & 0 \\ ⋮ & ⋮ & ⋱ & ⋮ & ⋮ & ⋮ & ⋱ & 0 \\ {h}_{R - 1 , 0} & {h}_{R - 1 , 1} & ⋯ & {h}_{R - 1 , C - 1} & 0 & 0 & ⋯ & 1\end{matrix} ] \times [ \begin{matrix}{m}_{0} \\ {m}_{1} \\ ⋮ \\ {m}_{C - 1} \\ {p}_{0} \\ {p}_{1} \\ ⋮ \\ {p}_{R - 1}\end{matrix} ] = 0 \qquad Equation 8$$

Equation 9 can be obtained from Equation 8.

$${\sum }_{j = 0}^{C - 1} {h}_{0 , j} {m}_{j} + {p}_{0} = 0 \\ {\sum }_{j = 0}^{C - 1} {h}_{1 , j} {m}_{j} + {p}_{1} = 0 \\ … \\ {\sum }_{j = 0}^{C - 1} {h}_{R - 1 , j} {m}_{j} + {p}_{R - 1} = 0 \qquad Equation 9$$

Since an addition operation is a modulo 2 operation (mod 2) in Equation 9, the parity can be determined as in Equation 10.

$${p}_{0} = {\sum }_{j = 0}^{C - 1} {h}_{0 , j} {m}_{j} \\ {p}_{1} = {\sum }_{j = 0}^{C - 1} {h}_{1 , j} {m}_{j} \\ … \\ {p}_{R - 1} = {\sum }_{j = 0}^{C - 1} {h}_{R - 1 , j} {m}_{j} \qquad Equation 10$$

In the LDPC code 1 which is an example of an LDPC code according to an embodiment of the present invention, the parity can be given as in Equation 11 since R=4, C=53, and Z=53.

p₀=Σⱼ₌₀⁵²h_{0,j}mⱼ,p₁=Σⱼ₌₀⁵²h_{1,j}mⱼ,p₂=Σⱼ₌₀⁵²h_{2,j}mⱼ;p₃=Σⱼ₌₀⁵²h_{R-1,j}mⱼ Equation 11

In h_{c,j}mⱼ of Equations 10 and 11, since h_{c,j} indicates circular shift of an identity matrix, h_{c,j}mⱼ indicates circular shift of a vector mⱼ. Accordingly, the i-th parity information pᵢ of the parity can be calculated by circularly shifting each information block mⱼ based on the i-th row of the H1 matrix.

Thus, the i-th parity information pᵢ may be implemented by hardware shown in FIG. 4.

Referring to FIG. 4, the i-th parity information generator 400 includes a circular shifter 410, a Z-bit exclusive OR (XOR) operator (XOR-Z) 420, and Z-bit register 430.

C blocks (m₀, m₁, . . . m_{C-1}) of units of Z bits into which the information m is divided are sequentially inputted to the circular shifter 410. In FIG. 4, mⱼ is the j-th block among the C blocks. The circular shifter 410 circularly shifts the block mⱼ of Z bits by h_{i,j}. The XOR-Z 420 performs a bitwise XOR operation on the block mⱼ which is circularly shifted in the circular shifter 410 and Z bits stored in the Z-bit register 430, and then a result of the bitwise XOR operation is stored in the Z-bit register 430. Accordingly, if these operations 410 to 430 are repeatedly performed on the sequentially inputted C blocks, that is, the operations 410 to 430 are repeatedly performed by incrementing j from 1 to C, a value stored in the Z-bit register 430 becomes the i-th parity information pᵢ. Assuming that a value stored in the Z-bit register 430 is 0 when the first block m₀ is inputted, a value outputted from the XOR-Z 420 is a value obtained by circularly shifting the block m₀ by h_{i,j}.

Referring to FIG. 5, an LDPC encoder 500 includes a plurality of parity generators 510. The plurality of parity generators 510 generate the first to R-th parity information (p₀, p₁, . . . p_{R-1}), respectively, and receives, as circular-shift values, h_{0,j}, h_{1,j}, . . . h_{R-1,j}, respectively.

Each parity generator 510 includes a circular shifter 511, an XOR-Z 512, and a Z-bit register 513 as described with reference to FIG. 4. C information blocks (m₀, m₁, . . . m_{C-1}) are sequentially inputted to the circular shifter 511 of each parity generator 510. The circular shifter 511 of each parity generator 510, for example, the i-th parity generator 510 circularly shifts the inputted block mⱼ of Z bits by the circular-shift value h_{i,j}. The XOR-Z 512 performs a bitwise XOR operation on the block mⱼ which is circularly shifted in the circular shifter 511 and Z bits stored in the Z-bit register 513, and then a result of the bitwise XOR operation is stored in the Z-bit register 513.

While the C information blocks (m₀, m₁, . . . m_{C-1}) are sequentially inputted, each parity generator 510 repeatedly performs these operations 511 to 513, and the LDPC encoder 500 sequentially outputs the information blocks (m₀, m₁, . . . M_{C-1}). Since the LDPC encoder 500 outputs the information blocks (m₀, m₁, . . . m_{C-1}) and the parity information (p₀, p₁, . . . p_{R-1}) generated in the parity generators 510 when the last information block m_{C-1} is inputted, the codeword (c=[m p]) can be generated.

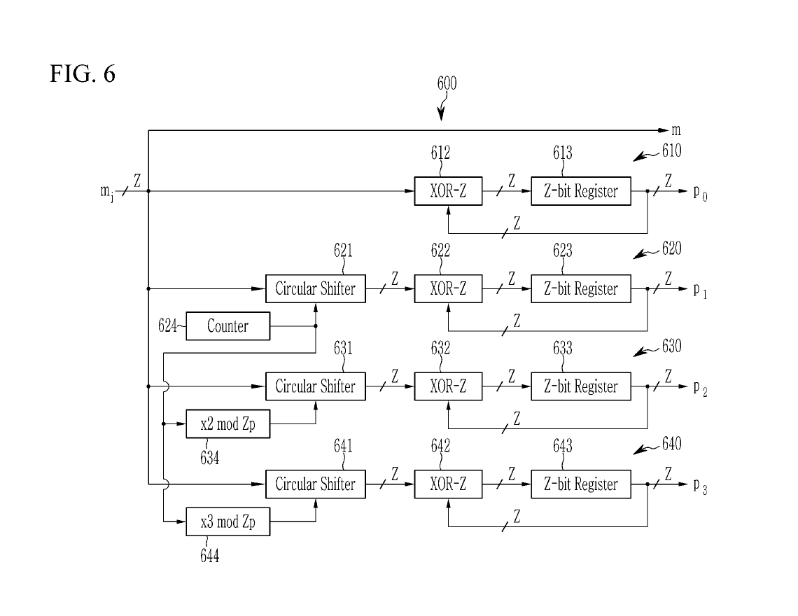

FIG. 6 is a schematic block diagram of an LDPC encoder according to another embodiment of the present invention. For convenience, it is assumed in FIG. 6 that the number (R) of rows is 4.

As described above, in a parity check matrix according to an embodiment of the present invention, all of elements in the first row are 0. Accordingly, each element of the first row is an identity matrix so that the inputted information m is outputted as it is. Elements of the second rows are incremented by 1 starting from 0. Elements of the third row are incremented by 2 starting from 0 and then modulo Z operation is performed on the elements. Elements of the fourth row are incremented by 3 starting from 0 and then modulo Z operation is performed on the elements. Accordingly, an LDPC encoder according to another embodiment of the present invention may be implemented by hardware shown in FIG. 6.

Referring to FIG. 6, an LDCP encoder 600 includes a plurality of parity generators 610, 620, 630, and 640.

As described above, since all of elements of the first row in a parity check matrix of an LDPC code according to an embodiment of the present invention are 0, circular shift is not performed. Therefore, the parity generator 610 for generating the first parity information p₀ includes an XOR-Z 612 and a Z-bit register 613. Whenever C information blocks (m₀, m₁, . . . m_{C-1}) of units of Z bits are sequentially inputted, the XOR-Z 612 performs a bitwise XOR operation on the information block mᵢ and Z bits stored in the Z-bit register 613, and then a result of the bitwise XOR operation is stored in the Z-bit register 613. Accordingly, after the last information block m_{C-1} is inputted, a value which is finally stored in the Z-bit register 613 is outputted as the first parity information p₀.

Since elements of the second row in the parity check matrix of the LDPC code are incremented by 1 starting from 0, a circular-shift value is incremented by 1 starting from 0 whenever the information blocks (m₀, m₁, . . . m_{C-1}) are sequentially inputted. Therefore, the parity generator 620 for generating the second parity information p₁ includes a circular shifter 621, an XOR-Z 622, a Z-bit register 623, and a counter 624. The counter 624 increments a counted value by 1 starting from 0 and generates the circular-shift value h_{i,j} by performing a modulo Z operation on the counted value. In some embodiments, when C is less than Z, the counter 624 outputs the counted value as the circular-shift value h_{1,j} without performing the modulo Z operation.

Accordingly, the counter 624 can deliver the circular-shift value h_{i,j} which is incremented by 1 starting from 0 to the circular shifter 621 whenever the information blocks (m₀, m₁, . . . m_{C-1}) are sequentially inputted. The circular shifter 621 circularly shifts the inputted block mⱼ of Z bits by the circular-shift value h_{1,j}. The XOR-Z 622 performs a bitwise XOR operation on the block mⱼ which is circularly shifted in the circular shifter 621 and Z bits stored in the Z-bit register 623, and then a result of the bitwise XOR operation is stored in the Z-bit register 623.

Since elements of the third row in the parity check matrix of the LDPC code are incremented by 2 starting from 0 and then modulo Z operation is performed on the elements, a circular-shift value is incremented by 2 starting from 0 and then modulo Z operation is performed on the circular-shift value whenever the information blocks (m₀, m₁, . . . m_{C-1}) are sequentially inputted. Therefore, the parity generator 630 for generating the third parity information p₂ includes a circular shifter 631, an XOR-Z 632, a Z-bit register 633 and a two-time modulo Z operator (×2 mod Zp) 634. The two-time modulo Z operator 634 doubles the counted value outputted from the counter 624 and generates the circular-shift value by performing the modulo Z operation on the doubled value. In this case, if a result of the modulo Z operation is equal to any one of the previously generated circular-shift value like the LDPC code 3, the two-time modulo Z operator 634 outputs the circular-shift value h_{2,j} by adding 1 to the result of the modulo Z operation.

Accordingly, the two-time modulo Z operator 634 can deliver the circular-shift value h_{2,j} to the circular shifter 631 whenever the information blocks (m₀, m₁, . . . m_{C-1}) are sequentially inputted. The circular shifter 631 circularly shifts the inputted block mⱼ of Z bits by the circular-shift value h_{2,j}. The XOR-Z 632 performs a bitwise XOR operation on the block mⱼ which is circularly shifted in the circular shifter 631 and Z bits stored in the Z-bit register 633, and then a result of the bitwise XOR operation is stored in the Z-bit register 633.

Since elements of the fourth row in the parity check matrix of the LDPC code are incremented by 3 starting from 0 and then modulo Z operation is performed on the elements, a circular-shift value is incremented by 3 starting from 0 and then modulo Z operation is performed on the circular-shift value whenever the information blocks (m₀, m₁, . . . m_{C-1}) are sequentially inputted. Therefore, the parity generator 640 for generating the fourth parity information p₃ includes a circular shifter 641, an XOR-Z 642, a Z-bit register 643 and a three-time modulo Z operator (×3 mod Zp) 644. The three-time modulo Z operator 644 triples the counted value outputted from the counter 624 and generates the circular-shift value h_{3,j} by performing the modulo Z operation on the tripled value. In this case, if a result of the modulo Z operation is equal to any one of the previously generated circular-shift value h_{3,j} like the LDPC code 3, the three-time modulo Z operator 644 outputs the circular-shift value h_{3,j} by adding 1 to the result of the modulo Z operation.

Accordingly, the three-time modulo Z operator 644 can deliver the circular-shift value h_{3,j} to the circular shifter 641 whenever the information blocks (m₀, m₁, . . . m_{C-1}) are sequentially inputted. The circular shifter 641 circularly shifts the inputted block mⱼ of Z bits by the circular-shift value h_{3,j}. The XOR-Z 642 performs a bitwise XOR operation on the block mⱼ which is circularly shifted in the circular shifter 641 and Z bits stored in the Z-bit register 643, and then a result of the bitwise XOR operation is stored in the Z-bit register 643.

While the C information blocks (m₀, m₁, . . . m_{C-1}) are sequentially inputted, the parity generators 610, 620, 630, and 640 repeatedly performs these operations to generate corresponding parity information (p₀, p₁, . . . p_{R-1}), and the LDPC encoder 600 sequentially outputs the information block (m₀, m₁, . . . m_{C-1}) as well. Since the LDPC encoder 600 outputs the information blocks (m₀, m₁, . . . m_{C-1}) and the parity information (p₀, p₁, . . . p_{R-1}) generated in the the parity generators 610, 620, 630, and 640 when the last information block m_{C-1} is inputted, the codeword (c=[m p]) can be generated.

As described above, according to an embodiment of the present invention, since the LDPC encoding can be performed by simple operational units such as the counter, the XOR calculator, and the register, the uncomplicated LDPC encoding method and LDPC encoder can be provided. Further, the overhead of the LDPC code can be reduced.

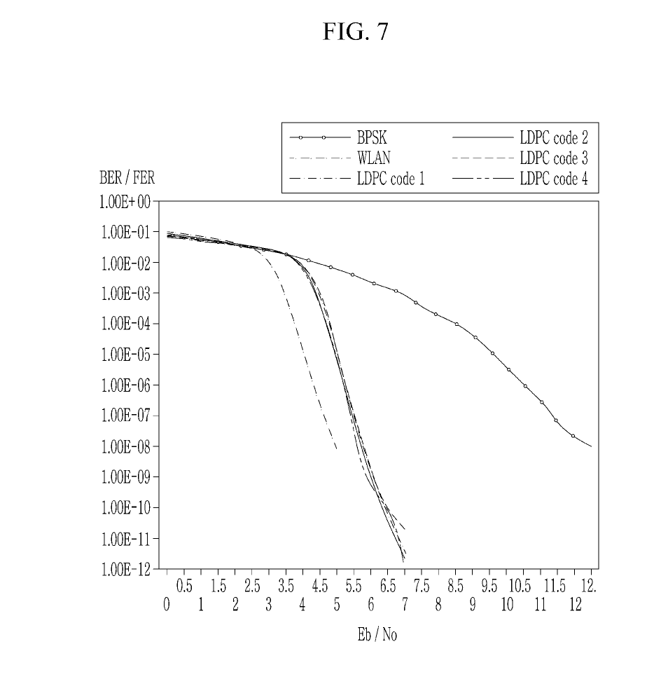

FIG. 7 is a drawing showing a performance of an LDPC code according to an embodiment of the present invention.

FIG. 7 shows a result of measuring a bit error rate (BER) performance in an additive white Gaussian noise (AWGN) environment after performing binary phase shift keying (BPSK) modulation on the LDPC code 1, the LDPC code 2, the LDPC code 3, and the LDPC code 4 described above. In FIG. 7, a horizontal axis represents a bit energy Eb for a noise power No, and a vertical axis represents the BER for a frame error rate (FER).

As shown in FIG. 7, it can be seen that the LDPC codes (LDPC codes 1 to 4) according to an embodiment of the present invention have a performance as good as about 0.75 dB at the level of 10⁻⁸ BER as compared with an LDPC code having an overhead of 20% used in a wireless LAN (WLAN), and are close to the unencoded BPSK performance. In particular, the BER performance over 10⁻¹² level can be provided for an optical communication system or a storage media system requiring extremely low BER performance.

As described above, using the LDCP encoding method according to an embodiment of the present invention can improve the error correction performance of the computing device. In particular, the error correction performance can be improved when a communication system or a storage medium system requiring the low BER performance transmits/receives data or reads/writes data.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A low-density parity-check (LDPC) encoding method of a computing device, comprising:
providing a parity check matrix with R rows and (C+R) columns defining an LDPC code; and
performing LDCP encoding on information with the parity check matrix,
wherein when the parity check matrix is divided into a first matrix with R rows and R columns and a second matrix with R rows and R columns, each element of the first matrix indicates a number of times an identity matrix with Z rows and Z columns are circularly shifted,
wherein all elements in the first row of the first matrix are 0,
wherein in the r-th row of the first matrix, elements obtained by performing a modulo Z operation (mod Z) on values which are sequentially incremented by (r−1) starting from 0 are arranged, and
wherein the R, the C, and the Z are natural numbers, and the r is an integer from 2 to R.

2. The LDPC encoding method of claim 1, wherein in the second matrix, a (r′,r′) element is 0 indicating an identity matrix with Z rows and Z columns, and remaining elements are −1 indicating a zero matrix with Z rows and Z columns, and
wherein the r′ is an integer from 1 to R.

3. The LDPC encoding method of claim 1, wherein when a certain element obtained by performing the modulo Z operation is equal to any one of previously arranged elements in the r-th row, the certain element is incremented by 1.

4. The LDPC encoding method of claim 1, wherein the C is equal to the Z.

5. The LDPC encoding method of claim 1, wherein the C is smaller than the Z.

6. The LDPC encoding method of claim 1, wherein the R is 4.

7. A low-density parity-check (LDPC) encoding method of a computing device, comprising:
sequentially inputting C blocks in units of Z bits into which information is divided;
performing a bitwise XOR operation on each of the sequentially inputted blocks and Z bits stored in a first register, storing a result of the bitwise XOR operation in the first register, and outputting a final value stored in the first register as the first parity information;
circularly shifting each of the sequentially inputted blocks by a circular-shift value corresponding to a value obtained by performing a modulo Z operation on a value which increments by (r−1) starting from 0, performing a bitwise XOR operation on the circularly-shifted value and Z bits stored in a r-th register, storing a result of the bitwise XOR operation in the r-th register, and outputting a final value stored in the r-th register as the r-th parity information; and
generating parity by sequentially outputting the first parity information and the r-th parity information,
wherein the Z, the C, and the R are natural numbers, and the r is an integer from 2 to (R−1).

8. The LDPC encoding method of claim 7, wherein circularly shifting each of the sequentially inputted blocks includes:
generating the value obtained by performing the modulo Z operation as the circular-shift value when the value obtained by performing the modulo Z operation is not equal to previously generated circular-shift values; and
generating a sum of one and the value obtained by performing the modulo Z operation as the circular-shift value when the value obtained by performing the modulo Z operation is equal to any one of the previously generated circular-shift values.

9. The LDPC encoding method of claim 7, wherein when the r is 2, circularly shifting each of the sequentially inputted blocks includes:
incrementing a counted value by 1 starting from 0 whenever the C blocks are sequentially inputted; and
outputting the counted value or a value obtained by performing the modulo Z operation on the counted value as the circular-shifted value.

10. The LDPC encoding method of claim 9, wherein when the r is an integer from 3 to (R−1), circularly shifting each of the sequentially inputted blocks includes:
multiplying the counted value or the value obtained by performing the modulo Z operation on the counted value by (r−1); and
generating the circular-shifted value using a value obtained by performing the modulo Z operation on the multiplied value.

11. The LDPC encoding method of claim 10, wherein when the r is an integer from 3 to (R−1), circularly shifting each of the sequentially inputted blocks further includes:
outputting the value obtained by performing the modulo Z operation on the multiplied value as the circular-shift value when the value obtained by performing the modulo Z operation on the multiplied value is not equal to previously generated circular-shift values; and
outputting a sum of one and the value obtained by performing the modulo Z operation on the multiplied value as the circular-shift value when the value obtained by performing the modulo Z operation on the multiplied value is equal to any one of the previously generated circular-shift values.

12. The LDPC encoding method of claim 7, further comprising outputting a codeword by combining the information with the parity.

13. The LDPC encoding method of claim 7, wherein the C is equal to the Z.

14. The LDPC encoding method of claim 7, wherein the C is smaller than the Z.

15. The LDPC encoding method of claim 7, wherein the R is 4.

16. A low-density parity-check (LDPC) encoder to which C blocks in units of Z bits into which information is divided are sequentially inputted, the LDPC encoder comprising:
R parity information generators,
wherein the first parity information generator among the R parity information generators includes a first XOR operator and a first register, and the first XOR operator performs a bitwise XOR operation on each of the sequentially inputted blocks and Z bits stored in the first register and stores a result of the bitwise XOR operation in the first register,
wherein the r-th parity information generator among the R parity information generators includes a r-th XOR operator and a r-th register, and the r-th XOR operator performs a bitwise XOR operation on a circularly-shifted value and Z bits stored in the r-th register and stores a result of the bitwise XOR operation in the r-th register, the circularly-shifted value being obtained by circularly shifting each of the sequentially inputted blocks by a circular-shift value corresponding to a value obtained by performing a modulo Z operation on a value which increments by (r−1) starting from 0, and
wherein the Z, the C, and the R are natural numbers, and the r is an integer from 2 to (R−1).

17. The LDPC encoder of claim 16, wherein when the r is 2, the r-th parity information generator further includes a counter, and
wherein the counter increments a counted value by 1 starting from 0 whenever the C blocks are sequentially inputted, and outputs the counted value or a value obtained by performing the modulo Z operation on the counted value as the circular-shifted value.

18. The LDPC encoder of claim 17, wherein when the r is an integer from 3 to (R−1), the r-th parity information generator further includes a (r−1)-multiplied modulo Z operator, and
wherein the (r−1)-multiplied modulo Z operator multiplies the value obtained by performing the modulo Z operation on an output of the counter by (r−1), and generates the circular-shifted value using a value obtained by performing the modulo Z operation on the multiplied value.

19. The LDPC encoder of claim 18, wherein the (r−1)-multiplied modulo Z operator outputs the value obtained by performing the modulo Z operation on the multiplied value as the circular-shift value when the value obtained by performing the modulo Z operation on the multiplied value is not equal to previously generated circular-shift values, and outputs a sum of one and the value obtained by performing the modulo Z operation on the multiplied value as the circular-shift value when the value obtained by performing the modulo Z operation on the multiplied value is equal to any one of the previously generated circular-shift values.

20. The LDPC encoder of claim 16, wherein a codeword is outputted by combining the information with outputs of the R parity information generators.
